(19) United States
(12) Patent Application Publication
(10) Pub. No.: US 2026/0269772 A1
(43) Pub. Date: Sep. 10, 2026

(54) INSTALLATION STRUCTURE FOR SOLAR CELL MODULE

(71) Applicant: KANEKA CORPORATION, Osaka (JP)

(72) Inventor: Nobumasa TAGAI, Osaka-shi (JP)

(73) Assignee: KANEKA CORPORATION, Osaka (JP)

(21) Appl. No.: 19/166,392

(22) PCT Filed: Mar. 18, 2024
(86) PCT No.: PCT/JP2024/010436

§ 371 Date: Sep. 17, 2025

(30) Foreign Application Priority Data
Mar. 23, 2023 (JP) 2023-046753

(51) Int. Cl. H02S 20/25; H10F 77/30

(52) U.S. Cl. CPC H02S 20/25; H10F 77/315

(57) ABSTRACT

Provided is an installation structure for a solar cell module, in which a distance L between an interrupting object and a light-receiving surface end part of a solar cell closest to the interrupting object satisfies two formulas below. A height of the interrupting object is defined as D; a start time for calculation is defined as a and an end time as b; and a sun altitude (in degrees) at a time i of a date k is defined as h_{k,i} and a solar azimuth angle (in degrees) as φ_{k,i}. An azimuth angle (in degrees) at which the installation surface faces is defined as R_{φ}, and an inclination angle (in degrees) of a light-receiving surface of the solar cell module is defined as R_{θ}. A date of the summer solstice is represented by k=1, and a date of the winter solstice is represented by k=2

$${L}_{k} = \frac{D}{b - a} {\int }_{a}^{b} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}} di$$

$${L}_{1} \leq L \leq {L}_{2} .$$

### CROSS-REFERENCE TO RELATED APPLICATION

This application claims priority to Japanese Patent Application No. 2023-046753, the disclosure of which is incorporated herein by reference in its entirety.

### FIELD

The present invention relates to an installation structure for a solar cell module including a solar cell string configured with a plurality of solar cells connected to each other.

### BACKGROUND

Proposed conventionally has been a solar cell module, a plurality of which are arranged on the roof of a house or the like (Patent Literature 1). Each solar cell module includes a glass substrate, a plurality of solar cells disposed on the glass substrate, and a frame at an outer peripheral edge. In this solar cell module, there are some cases where a part of the solar cell module or a structure adjacent to the solar cell module interrupts sunlight to cast a shadow on some of the solar cells. To avoid this, those solar cells which sunlight may not reach are made wider than the other solar cells.

### CITATION LIST

### Patent Literature

Patent Literature 1: JP 2000-349326 A

### SUMMARY

### Technical Problem

As described above, there are some cases where the part of the solar cell module or the structure adjacent to the solar cell module serves as an interrupting object for the solar cells, interrupting sunlight from reaching some of the solar cells. In such cases, the entire solar cell module including those solar cells which sunlight reaches has degraded power generation efficiency, which is a problem.

It is an object of the present invention to provide an installation structure for a solar cell module configured to suppress power output from being degraded by an interrupting object.

### Solution to Problem

An installation structure for a solar cell module according to the present invention is an installation structure for a solar cell module including a solar cell string configured with a plurality of solar cells connected to each other, in which the solar cell module is disposed at a position shaded by an interrupting object that interrupts part of direct sunlight toward the solar cell module during a certain period of time of a day in a certain season, and a distance L between the interrupting object and a light-receiving surface end part of a solar cell closest to the interrupting object among the plurality of solar cells satisfies two formulas below:

$${L}_{k} = \frac{D}{b - a} {\int }_{a}^{b} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}} di$$

$${L}_{1} \leq L \leq {L}_{2}$$

where D represents a height of the interrupting object with respect to an installation surface of the solar cell module (height in a normal direction of the installation surface);
a represents a start time (hour-based) of a time range for which calculation is performed, and b represents an end time (hour-based) thereof;
in a zone to which an installation location of the solar cell module belongs, h_{k,i} represents a sun altitude (in degrees) at a time (hour-based) i of a date k, and φ_{k,i} represents a solar azimuth angle (in degrees) in a north reference left-handed system;
R_{φ} represents an azimuth angle (in degrees) in the north reference left-handed system at which the installation surface of the solar cell module faces, and R_{θ} represents an inclination angle (in degrees) of a light-receiving surface of the solar cell module relative to a horizontal plane; and
k=1 represents a date of the summer solstice, and k=2 represents a date of the winter solstice.

In the installation structure for the solar cell module, the configuration can also be such that the distance L between the interrupting object and the light-receiving surface end part of the solar cell closest to the interrupting object among the plurality of solar cells further satisfies two formulas below:

$${L}_{k} = \frac{D}{6} {\sum }_{i = 9}^{14} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}}$$

$${L}_{1} \leq L \leq {L}_{2}$$

where, in the zone to which the installation location of the solar cell module belongs, h_{k,i} represents a sun altitude (in degrees) at a time i:30 on the date k, and φ_{k,i} represents a solar azimuth angle (in degrees) in the north reference left-handed system.

In the installation structure for the solar cell module, the configuration can also be such that the solar cell string is formed of the plurality of solar cells connected to each other by shingling connection.

In the installation structure for the solar cell module, the configuration can also be such that the solar cell module is installed at −90 to 90 degrees in the Northern Hemisphere, and at 90 to 270 degrees in the Southern Hemisphere, in the north reference left-handed system.

In the installation structure for the solar cell module, the configuration can also be such that the installation surface is a surface of a roof of a building.

In the installation structure for the solar cell module, the configuration can also be such that the solar cell module includes a light-transmitting layer on a light incident side, and the light-transmitting layer is subjected to an antiglare treatment.

### BRIEF DESCRIPTION OF DRAWINGS

FIG. 1 is a schematic plan view of a solar cell module according to this embodiment.

FIG. 2 is a schematic cross-sectional view taken along line II-II in FIG. 1.

FIG. 3 is a graph showing the transition in a power generation amount when the solar cell module is used.

FIG. 4 is a graph showing the transition in a power generation amount when a solar cell module according to a comparative example is used.

### DESCRIPTION OF EMBODIMENTS

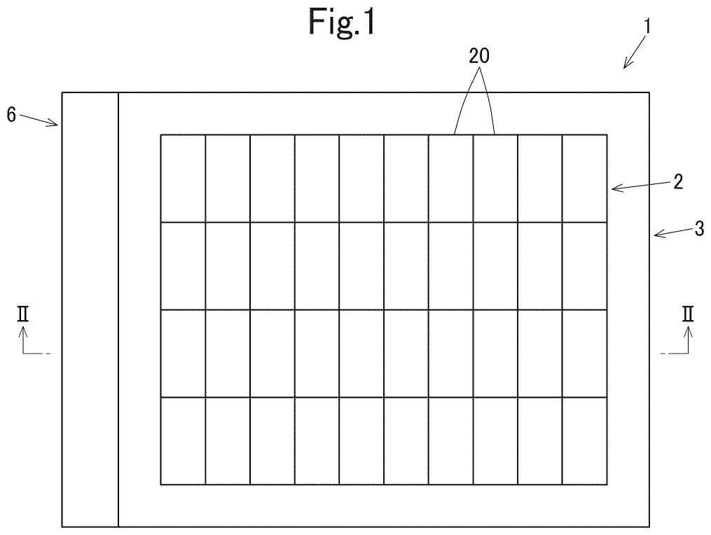

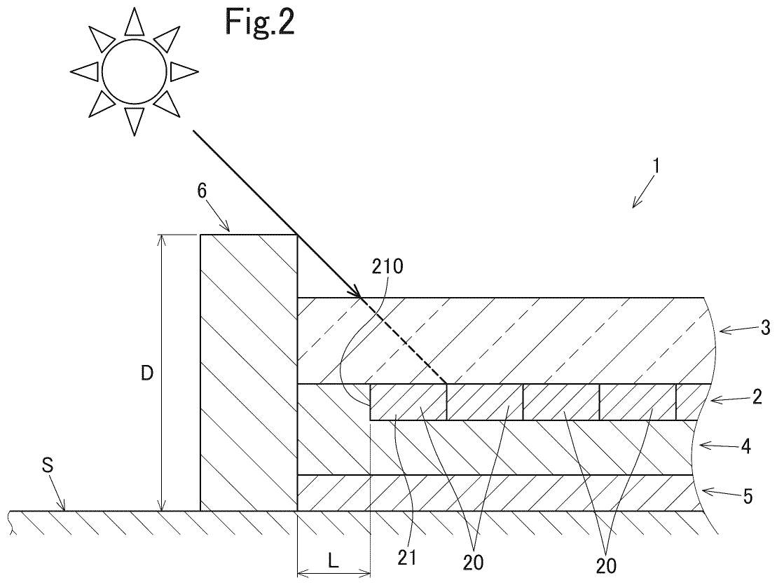

A description will be hereinafter given on an installation structure for a solar cell module according to an embodiment of the present invention with reference to FIG. 1 and FIG. 2. The installation structure for the solar cell module is an installation structure for a solar cell module 1 including a solar cell string 2 configured with a plurality of solar cells 20 connected to each other. The solar cell module 1 includes the solar cell string 2 and a light-transmitting layer 3 disposed on a light incident side. The solar cell module 1 further includes a sealing material 4 and a resin sheet 5, which are disposed on a back surface of the solar cell string 2. The solar cell module 1 can include a frame disposed on an outer edge of the light-transmitting layer 3. This solar cell module 1 has a plate shape, and is, for example, installed on an installation surface S with a main surface (light-receiving surface) facing upward (facing the sun).

As shown in FIG. 2, the solar cell module 1 is disposed at a position shaded by an interrupting object 6 that interrupts part of direct sunlight toward the solar cell module 1 during a certain period of time of a day in a certain season. In this solar cell module 1, a distance L between the interrupting object 6 and a light-receiving surface end part 210 of a solar cell 21 closest to the interrupting object 6 out of the plurality of solar cells 20 satisfies the following two formulas. The distance L between the interrupting object 6 and the light-receiving surface end part 210 of the solar cell 21 is a distance in a direction along the installation surface S. The installation surface S of the solar cell module 1 is, for example, a surface of a roof of a building, and in the case where the solar cell module 1 is a “type designed to be integrated with a roof”, the installation surface S is a surface of a sheathing roof board or a waterproof sheet placed on the sheathing roof board.

$${L}_{k} = \frac{D}{b - a} {\int }_{a}^{b} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}} di$$

$${L}_{1} \leq L \leq {L}_{2}$$

In the above formula, the height of the interrupting object 6 with respect to the installation surface S (i.e., height in a normal direction of the installation surface S) of the solar cell module 1 is defined as D. The start time (hour-based) of a time range for which calculation is performed is defined as a, and the end time (hour-based) thereof as b. In a zone to which an installation location of the solar cell module 1 belongs, a sun altitude (in degrees) at a time i of a date k is defined as h_{k,i} and a solar azimuth angle (in degrees) in the north reference left-handed system is defined as φ_{k,i}. An azimuth angle (in degrees) in the north reference left-handed system at which the installation surface S of the solar cell module 1 faces is defined as R_{φ}. Further, an inclination angle (in degrees) of the light-receiving surface of the solar cell module 1 relative to the horizontal plane is defined as R_{θ}. In the configuration of FIG. 2, the inclination angle (in degrees) R_{θ} of the light-receiving surface of the solar cell module 1 relative to the horizontal plane is, for example, 90 degrees. Furthermore, k=1 is defined as the date of the summer solstice, and k=2 as the date of the winter solstice. In this embodiment, the “summer solstice” refers to the day when the culmination altitude of the sun (i.e., altitude of the sun when located due south as viewed in the Northern Hemisphere) is highest (i.e., the day with the longest daytime of a year), while the “winter solstice” refers to the day when the culmination altitude of the sun (i.e., altitude of the sun when located due south as viewed in the Northem Hemisphere) is lowest (i.e., the day with the shortest daytime of a year). For example, the “summer solstice” occurs from June 20th to 22nd in the Northern Hemisphere, and from December 21st to 23rd in the Southern Hemisphere. In other words, in the Northern Hemisphere, the “summer solstice” refers to the day that includes the time at which the ecliptic plane is located furthest north from the equatorial plane while the “winter solstice” refers to the day that includes the time at which the ecliptic plane is located furthest south from the equatorial surface. In the Southern Hemisphere, the “summer solstice” refers to the day that includes the time at which the ecliptic plane is located furthest south from the equatorial plane while the “winter solstice” refers to the day that includes the time at which the ecliptic plane is located furthest north from the equatorial plane (i.e., opposite from the Northern Hemisphere).

According to this installation structure for the solar cell module 1 in which the distance L between the interrupting object 6 and the light-receiving surface end part 210 of the solar cell 21 closest to the interrupting object 6 is set using the above two formulas, the solar cell module 1 is shaded only during a limited period of time of the day in a limited season while the solar cell module 1 is disposed close to the interrupting object 6, thereby being capable of minimizing the effect of the shadow cast by the interrupting object 6. The configuration that the effect of the shadow cast by the interrupting object 6 is thus minimized can suppress the power output of the solar cell module 1 from being degraded by the interrupting object 6.

A description will be hereinafter given on a method for deriving the above two formulas. To derive these two formulas, a first step to begin with is to express the relationship between the roof and the sun as a three-dimensional vector, followed by finding a shadow vector. Then, a second step is to express each vector in the Cartesian coordinates via the spherical polar coordinates to obtain a value allowing numerical calculation.

A specific description will be given on how to determine the shadow vector. First, consider the case where a single rod with the height D stands along the normal direction of the roof surface (i.e., installation surface). At this time, a shadow is cast at a line extending from the line between the sun and the tip of the rod. Here, as unit vectors, VS (a unit vector from the roof toward the sun) and VR_{N} (a normal vector to the roof surface) are set as follows. These vectors include information on the position of the sun, and the angle and azimuth of the roof.

The first step is to calculate the vector of the shadow cast by the single rod standing on the roof. A vector in which the unit vector VS from the roof surface toward the sun is projected on the roof normal vector VR_{N} is (VS·VR_{N}) VR_{N}. The projected vector is subtracted from the original vector VS to obtain the component on the roof surface (i.e., vector obtained by projecting VS on the roof surface). When this is expressed as VRₕ, the following formula is obtained:

$$\vec{{S}_{h}} = \vec{S} - ( \vec{S} \cdot \vec{{R}_{N}} ) \vec{{R}_{N}}$$

Where an angle between VS and VR_{N} is expressed as α,

$$\vec{S} \cdot \vec{{R}_{N}} = cos α$$

thus, the length of the shadow cast by the rod is |D tan α|. Thus, where the vector of the shadow cast by the rod is expressed as VS_{H}, which is obtained by converting VSₕ into a unit vector and then multiplying the unit vector by |D tan α|, the following formula can be obtained.

$$\vec{{S}_{H}} = \frac{\vert D tan α \vert}{\vert \vec{{S}_{h}} \vert} \vec{{S}_{h}} = \frac{\vert D tan α \vert}{\vert \vec{S} - ( \vec{S} \cdot \vec{{R}_{N}} ) {R}_{N} \vert} \vec{{S}_{h}}$$

Where:

$$\begin{matrix}\frac{\vert D tan α \vert}{\vert \vec{S} - ( \vec{S} \cdot \vec{{R}_{N}} ) {R}_{N} \vert} = \frac{\vert D tan α \vert}{\sqrt{{\vert \vec{S} \vert}^{2} + {( \vec{S} \cdot \vec{{R}_{N}} )}^{2} {\vert \vec{{R}_{N}} \vert}^{2} - 2 {( \vec{S} \cdot \vec{{R}_{N}} )}^{2}}} \\ = \frac{\vert D tan α \vert}{\sqrt{1 - {cos}^{2} α}} \\ = \frac{\vert D tan α \vert}{\vert sin α \vert} \\ = \frac{D}{\vert cos α \vert}\end{matrix}$$

holds; thus,

$$\vec{{S}_{H}} = \frac{D}{\vert cos α \vert} ( \vec{S} - cos α \vec{{R}_{N}} )$$

is obtained.

On the actual roof, the interrupting object 6 is not a single rod but has a stepped structure. Therefore, a situation shall be considered where an infinite number of these rods are present in a width direction of the roof. The shadow cast by this step is given by the component in a roof length direction (perpendicular to the step extending in the width direction) of the vector of the shadow cast by the single rod. A unit vector VR_{H} in the roof length direction (perpendicular to the step extending in the width direction) of the vector of the shadow is determined by orthographically projecting the previously obtained VS_{H} onto VR_{H}.

The vector obtained by projecting VS_{H} onto VR_{H} is (VR_{H}·VS_{H})VR_{H}. Here, the angle between VS_{H} and VR_{H} is defined as γ. Making use that the inner product of VR_{H} and VR_{N}, which are orthogonal to each other, is zero, the following formula is obtained:

$$\begin{matrix}( \vec{{R}_{H}} \cdot \vec{{S}_{H}} ) \vec{{R}_{H}} = \frac{D}{\vert cos α \vert} \{ \vec{{R}_{H}} \cdot ( \vec{S} - cos α \vec{{R}_{N}} ) \} \vec{{R}_{H}} \\ = \frac{D}{\vert cos α \vert} ( \vec{{R}_{H}} \cdot \vec{S} ) \vec{{R}_{H}} \\ = D \frac{\vert cos γ \vert}{\vert cos α \vert} \vec{{R}_{H}}\end{matrix}$$

When the following formula holds, the sun is located on a back side of the front surface (installation surface) of the roof, and does not irradiate any part of the roof with direct sunlight:

$$\vec{S} < 0 ( ⇔ 90 ° < α < 270 ° , 270 ° < α < 360 ° )$$

When the following formula holds, a shadow is cast from a lower side of the front surface of the roof (i.e., installation surface) to an upper side (i.e., in a direction of the roof ridge). However, in the stepped structure considered in this case, no such shadow as flowing from the lower side to the upper side is cast, and thus the entire roof is irradiated with direct sunlight:

$$\vec{S} > 0 ( ⇔ 0 ° < γ < 90 ° )$$

Accordingly, the actual shadow is cast only when

$$\vec{S} > 0 and \vec{S} < 0$$

At this time, the following formula holds:

$$cos α > 0 , cos γ < 0$$

Thus, the following value is obtained as the “vector of the shadow cast by the rod standing on the roof”:

$$D \frac{cos γ}{cos α}$$

The second step is to express each vector in the Cartesian coordinates via the spherical polar coordinates to obtain a value allowing numerical calculation. The movement of the sun as viewed from an observation point is derived in the spherical coordinate system. In order to obtain a value allowing numerical calculation, therefore, the “vector of the shadow cast by the rod standing on the roof” needs to be determined in the spherical coordinate system, followed by converting the vector in the Cartesian coordinate system for calculations such as the inner product.

Specifically, the length of the shadow is obtained where the sun altitude is h and the solar azimuth is φ at a given date and time, and the roof installed at a roof azimuth R_{φ} and an inclination R_{θ} has the step having the height D. The sun altitude h is the angle of the sun with the horizon being 0° and the zenith (directly above the observer) being 90°, and the zenith is considered to coincide with θ in the spherical coordinate system; thus, the relationship of θ=90°−h holds. The solar azimuth φ and the roof azimuth R_{φ} are expressed in the north reference left-handed system, and are converted in the east reference right-handed system for use in vector calculations. The north reference left-handed system is a clockwise system with the north being 0 degrees, and the east reference right-handed system is a counterclockwise system with the east being 0 degrees. In the general xy coordinate, the positive direction of the x axis is directed east while the positive direction of the y axis is directed north. The solar azimuth φ calculated in the north reference left-handed system is converted to 90°−φ in the east reference right-handed system. For example, as shown in the table below, southeast is expressed as 135 degrees in the north reference left-handed system, which shall be 90°−135°=−45°, i.e., 315° in the east reference right-handed system.

TABLE 1

| | Reference | | |
|---|---|---|---|
| | North reference | South reference | East reference |
| Azimuth | left-handed | left-handed | right-handed |
| North | 0°/360° | 180° | 90° |
| East | 90° | 270° | 0°/360° |
| South | 180° | 0°/360° | 270° |
| West | 270° | 90° | 180° |

Taking the above into consideration, in the spherical coordinate system, VS, VR_{N}, and VR_{H} are as follows. For VR_{N} and VR_{H}, intuitive understanding can be achieved after parallel translation of the vectors to be obtained therefor to the origin. Also, all these vectors are unit vectors, and thus r=1.

$$\vec{S} = ( \begin{matrix}1 \\ 90 ° - h \\ 90 ° - ϕ\end{matrix} )$$

$$\vec{{R}_{N}} = ( \begin{matrix}1 \\ {R}_{θ} \\ 90 ° - {R}_{ϕ}\end{matrix} )$$

$$\vec{{R}_{H}} = ( \begin{matrix}1 \\ 90 ° + {R}_{θ} \\ 90 ° - {R}_{ϕ}\end{matrix} )$$

Next, the vectors expressed in the spherical polar coordinates are converted in the Cartesian coordinates.

$$\vec{S} = ( \begin{matrix}sin ( 90 ° − h ) cos ( 90 ° − ϕ ) \\ sin ( 90 ° − h ) sin ( 90 ° − ϕ ) \\ cos ( 90 ° − h )\end{matrix} ) = ( \begin{matrix}cos h sin ϕ \\ cos h cos ϕ \\ sin h\end{matrix} )$$

$$\vec{{R}_{N}} = ( \begin{matrix}sin {R}_{θ} cos ( 90 ° − {R}_{ϕ} ) \\ sin {R}_{θ} sin ( 90 ° − {R}_{ϕ} ) \\ cos {R}_{θ}\end{matrix} ) = ( \begin{matrix}sin {R}_{θ} sin {R}_{ϕ} \\ sin {R}_{θ} cos {R}_{ϕ} \\ cos {R}_{θ}\end{matrix} )$$

$$\vec{{R}_{H}} = ( \begin{matrix}sin ( 90 ° + {R}_{θ} ) cos ( 90 ° − {R}_{ϕ} ) \\ sin ( 90 ° + {R}_{θ} ) sin ( 90 ° − {R}_{ϕ} ) \\ cos ( 90 ° + {R}_{θ} )\end{matrix} ) = ( \begin{matrix}cos {R}_{θ} sin {R}_{ϕ} \\ cos {R}_{θ} cos {R}_{ϕ} \\ − sin {R}_{θ}\end{matrix} )$$

The inner product can be thereby obtained as follows:

$$\begin{matrix}\vec{S} \cdot \vec{{R}_{N}} = ( \begin{matrix}cos h sin ϕ \\ cos h cos ϕ \\ sin h\end{matrix} ) \cdot ( \begin{matrix}sin {R}_{θ} sin {R}_{ϕ} \\ sin {R}_{θ} cos {R}_{ϕ} \\ cos {R}_{θ}\end{matrix} ) \\ = cos h sin ϕ sin {R}_{θ} sin {R}_{ϕ} + cos h cos ϕ sin {R}_{θ} cos {R}_{ϕ} + sin h cos {R}_{θ}\end{matrix}$$

$$\begin{matrix}\vec{S} \cdot \vec{{R}_{H}} = ( \begin{matrix}cos h sin ϕ \\ cos h cos ϕ \\ sin h\end{matrix} ) \cdot ( \begin{matrix}cos {R}_{θ} sin {R}_{ϕ} \\ cos {R}_{θ} cos {R}_{ϕ} \\ - sin {R}_{θ}\end{matrix} ) \\ = cos h sin ϕ cos {R}_{θ} sin {R}_{ϕ} + cos h cos ϕ cos {R}_{θ} cos {R}_{ϕ} − sin h sin {R}_{θ}\end{matrix}$$

Therefore, the length of the shadow is calculated as follows:

$$\begin{matrix}− D \frac{cos γ}{cos α} = − D \frac{( \vec{S} \cdot \vec{{R}_{H}} )}{( \vec{S} \cdot \vec{{R}_{N}} )} \\ = − D \frac{\begin{matrix}cos h sin ϕ cos {R}_{θ} sin {R}_{ϕ} + \\ cos h cos ϕ cos {R}_{θ} cos {R}_{ϕ} − sin h sin {R}_{θ}\end{matrix}}{\begin{matrix}cos h sin ϕ sin {R}_{θ} sin {R}_{ϕ} + \\ cos h cos ϕ sin {R}_{θ} cos {R}_{ϕ} + sin h cos {R}_{θ}\end{matrix}}\end{matrix}$$

From the above, an average shadow length L from the start time a (hour-based) to the end time b (hour-based) satisfies the following two formulas where k=1 is the date of the summer solstice and k=2 is the date of the winter solstice. The dates of the summer solstice and the winter solstice are the dates of the year for which the evaluation is performed using each of the following formulas.

$${L}_{k} = \frac{D}{b - a} {\int }_{a}^{b} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}} di$$

$${L}_{1} \leq L \leq {L}_{2}$$

In this embodiment, the distance L between the interrupting object 6 and the light-receiving surface end part 210 of the solar cell 21 closest to the interrupting object 6 among the plurality of solar cells 20 satisfies the following two formulas. These formulas use the summation symbol (Σ) as a discrete function for the sake of convenience in calculation although the formula using the integral symbol above is a continuous function.

$${L}_{k} = \frac{D}{6} {\sum }_{i = 9}^{14} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}}$$

$${L}_{1} \leq L \leq {L}_{2}$$

In the above formula, the sun altitude (in degrees) at the time i:30 on the date k is h_{k,i} and the solar azimuth angle (in degrees) in the north reference left-handed system is φ_{k,i}, in the zone to which the installation location of the solar cell module belongs. That is, Lₖ is calculated using the sum of the values at six points for each hour from 9:30 to 14:30. The start time, the end time, and the time interval of the time range for which the calculation is performed can be set using a formula other than that described above.

In this embodiment, the installation surface S of the solar cell module 1 is the front surface of the roof of a building, as described above. Even in the case where the solar cell module 1 is installed on the roof, which is considered to be one of the major installation examples, the effect of the shadow cast by the interrupting object 6 can still be minimized.

In this embodiment, the solar cell module 1 is installed at an azimuth angle of 90 to 270 degrees in the north reference left-handed system. Such a configuration can minimize the effect of the shadow cast by the interrupting object 6 when the solar cell module 1 is installed to face north in the Northern Hemisphere.

In this embodiment, each of the solar cells 20 of the solar cell string 2 is formed in an elongated shape. The solar cell string 2 is formed of, for example, the plurality of solar cells 20 interconnected with each other by shingling connection. The shingling connection refers to a connection of the solar cells 20 in an elongated shape that are sequentially arranged to have their long sides overlapping each other, as in a manner for shingling roof boards. In the solar cell string 2 of this embodiment, the solar cells 20 are connected to each other in series. The solar cells 20 share the same size (i.e., the same width dimension of the solar cells 20 in the solar cell string 2 formed by the shingling connection) with each other. Each solar cell 20 has, for example, a rectangular and substantially rectangular plate shape.

In the case where the solar cell string 2 is formed by the shingling connection, the above configuration enables a distance between the solar cell string 2 and the interrupting object 6 or another solar cell module 1 to be optimally adjusted by the number of solar cells 20 connected in series and the width of overlapping between each adjacent ones of the solar cells 20. In order to adjust the distance between the solar cell string 2 and the interrupting object 6 or another solar cell module 1, a possible option may be to change the width of the solar cell 20 itself (see, for example, Patent Literature 1); for this change, however, the printing design of the electrode formed on the solar cells 20 needs to be changed due to a restriction in the size of a silicon wafer as a material of the solar cells 20. It is therefore easier to change the number of solar cells 20 connected to each other in series or the width of overlapping between each adjacent ones of the solar cells 20 than to change the width of each solar cell 20 itself. Thus, the approach according to this embodiment is more advantageous.

The light-transmitting layer 3 is a light-transmitting protective plate that is layered on the light incident side of the solar cell string 2. The light-transmitting layer 3 is, for example, a glass plate. Further, the light-transmitting laver 3 has the sealing material 4 adhering thereto. In this embodiment, the light-transmitting layer 3 is subjected to an antiglare treatment. The antiglare treatment is performed by a blasting treatment in which a polishing material is obliquely blasted onto a glass plate as a material for the light-transmitting layer 3 to form unevenness on a surface on the light incident side. When the solar cell module 1 is installed to face north in the Northern Hemisphere or the solar cell module 1 is installed to face south in the Southern Hemisphere, this treatment can effectively suppress light pollution, which might occur in an area adjacent to the installation location depending on an angle of light reflection.

The sealing material 4 is, for example, layered on a back surface of the solar cell string 2. The sealing material 4 is, for example, a resin layer. Further, the sealing material 4 also covers an end surface (outer periphery) of the solar cell string 2.

An experiment was conducted to measure the amount of power generated by the solar cell module 1 described above using a mock roof installed in Toyooka City, Hyogo Prefecture, Japan and at an azimuth angle of −13° (13° west of true north) in the north reference left-handed system. The solar cell module 1 was installed on this roof so that the inclination angle of the solar cell module 1 was 15.3 degrees from the horizontal plane and the height of the step resulting from the upper part of the solar cell module (i.e., height of the interrupting object 6 with respect to the installation surface S of the solar cell module 1) was D=36 mm. The solar cell module 1 installed under the conditions had an average shadow length at the summer solstice of L1=14.7 mm, and had an average shadow length at the winter solstice of L2=199.7 mm. The distance (L) from the step (interrupting object 6) of the solar cell module 1 to the solar cells was measured for a solar cell module of the example with L=40 mm and a solar cell module of the comparative example with L=8 mm, on sunny days (different days) in early August. The example and the comparative example share the same module shape and the same width of the solar cells of 24 mm, and are configured to adjust the value L by decreasing the number of cells connected to each other in series by 10%.

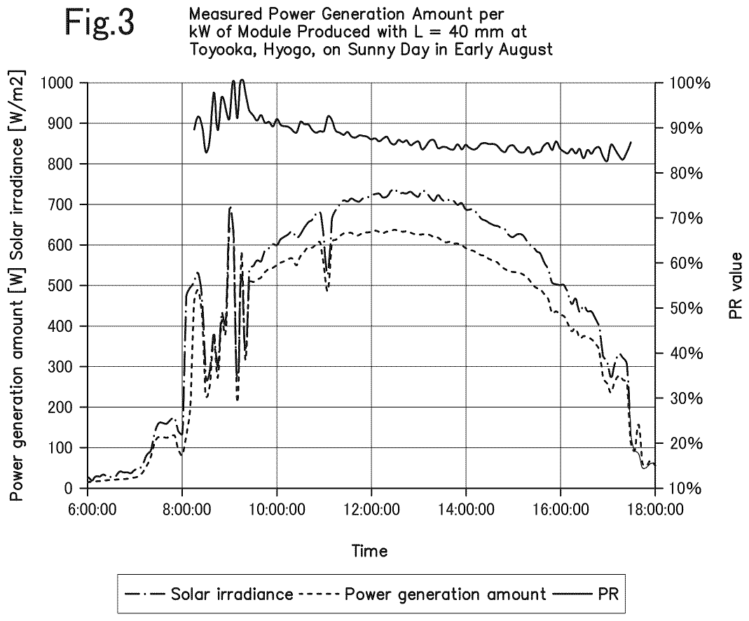

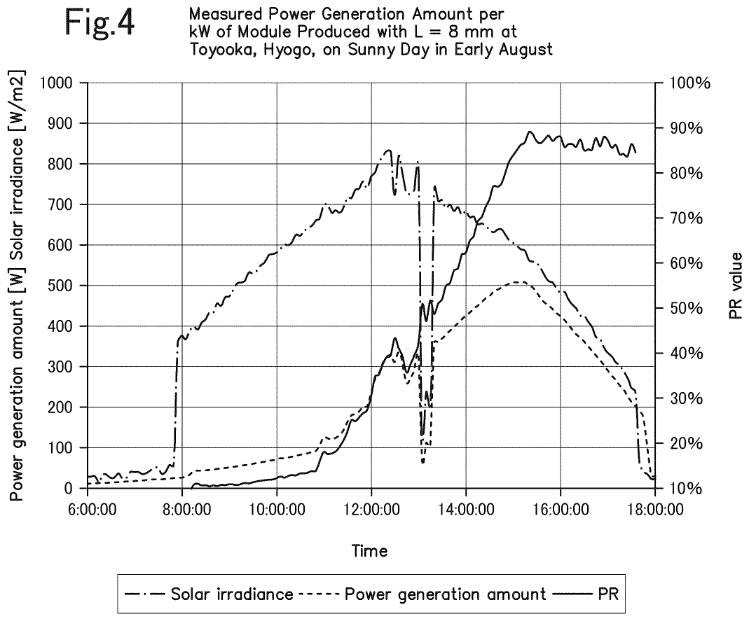

A plurality of the solar cell modules installed on the mock roof and connected to each other in series were connected with an IV curve tracer to obtain an IV curve once every five minutes for measurement of power output (Pmax) at the optimal operating point each time. The Pmax was divided by the sum of the Pmax values of the modules measured in advance using a solar simulator under the Standard Test Condition, and the result was plotted on a corresponding one of the graphs of FIG. 3 and FIG. 4 as an instantaneous power generation amount (unit: W) per unit installation amount (1 kW). The instantaneous value of solar irradiance (unit: W/m²) measured using a pyranometer was also plotted on the graph of the Figure. Further, the instantaneous power generation amount/instantaneous solar irradiance was plotted as the instantaneous PR (Performance Ratio) on the same graph of the Figure.

It can be found in the example (FIG. 3) that the effect of the shadow cast by the solar cell module 1 is suppressed and the instantaneous PR is kept at a high level of 80 to 90%. In the comparative example (FIG. 4), on the other hand, the first cell in the solar cell string 2 (i.e., the closest cell to the interrupting object 6) is shaded in the morning. Thus, the “instantaneous PR is only about 10 to 30% in the morning, but recovers to 80% to 90% after 15:00 in the case of the measurement with this particular mock roof installed at an azimuth angle of 13° west of north, on which the shadow becomes shorter toward the evening.

The sum of the instantaneous power generation amount and the sum of the instantaneous solar irradiance values, which are respectively measured once every five minutes, are each divided by 12000 to obtain an integrated power generation amount (unit: kWh) and an integrated solar irradiance (unit: kWh/m²) on a daily basis. In the example (FIG. 3), the integrated power generation amount is 4.99 kWh and the integrated solar irradiance is 5.74 kWh/m², while in the comparative example (FIG. 4), the integrated power generation amount is 2.52 kWh and the integrated solar irradiance is 5.57 kWh/m². The PR of the integrated values is 86.9% in the example (FIG. 3) and 45.2% in the comparative example (FIG. 4). It should be noted that the number of solar cells used for the example is smaller by 10% to make longer the distance between the interrupting object 6 and the solar cells; thus, the example has a power output smaller by 10% than that of the comparative example if no shadow is cast. In this measurement result, however, the difference in PR between the example and the comparative example is greater than 10%, showing that the example is more advantageous.

Further, a simulation was performed for the solar cell module 1 described above, using a sample including the solar cell string 2 in which the solar cells 20 were connected in series. In this simulation, a matrix was set between the distance (L) from the step (interrupting object 6) of the solar cell module 1 to the solar cells and the installation azimuth of the roof (at an azimuth angle of 0° (installed to face north) to 90° (installed to face east) in the north reference left-handed system), and an annual power generation amount was calculated. Specifically, L was set to 0, 5, 10, 15, 20, 30, 40, 50, 75, 100, 150, and 200 mm. This L was set by changing the number of solar cells 20 connected in series or the width of overlapping between each adjacent ones of the solar cells 20. The installation azimuth of the roof was set to north (0° in the north reference left-handed system; the same applies below), north-northeast (22.5°), northeast (45°), east-northeast (67.5°), and east (90°).

In this simulation, the NEDO database METPV-20 (normal year data) was used to estimate the hourly solar irradiance on a tilted plane using the method described in the New Solar Energy Utilization Handbook. The length of the shadow cast by the step (interrupting object 6) was calculated every hour using the following formula.

$${L}_{m , i} = \frac{\begin{matrix}- cos {h}_{m , i} sin {ϕ}_{m , i} cos {R}_{θ} sin {R}_{ϕ} - \\ cos {h}_{m , i} cos {ϕ}_{m , i} cos {R}_{θ} cos {R}_{ϕ} + sin {h}_{m , i} sin {R}_{θ}\end{matrix}}{\begin{matrix}cos {h}_{m , i} sin {ϕ}_{m , i} sin {R}_{θ} sin {R}_{ϕ} + \\ cos {h}_{m , i} cos {ϕ}_{m , i} sin {R}_{θ} cos {R}_{ϕ} + sin {h}_{m , i} cos {R}_{θ}\end{matrix}}$$

The calculated shadow length and the width w of the solar cell were used to calculate a proportion ρ of a shaded area out of the solar cell closest to the step (interrupting object 6), using the following formula, where ρ=0 is set when ρ is less than 0, and ρ=1 is set when ρ is greater than 1.

$${ρ}_{m , i} = \frac{{L}_{1} - 1}{w}$$

Further, the reduction in direct solar irradiance I by the proportion ρ was calculated using the following formula. An effective tilted plane solar irradiance (I_{eff,tilt}) taking the effect of the shadow into account was obtained by multiplying the “proportion ρ of the shaded area” by a tilted plane solar irradiance (Iₜᵢₗₜ) not taking the effect of the shadow into account. The amount of power generated per 1 kW installation was set using the method according to JIS8907 for the tilted plane solar irradiance taking the effect of the shadow in account. Each solar irradiance is a function of the date m and the time i, but subscripts are omitted.

$${I}_{eff , tilt} = {I}_{tilt} - {ρ}_{m , i} \times {I}_{dir , tilt}$$

The installation location was in Osaka Prefecture, Japan. The roof angle R_{θ} (the inclination angle (in degrees) of the light-receiving surface of the solar cell module 1 relative to the horizontal plane) was set to 20.25°, and the width of a light-receiving area of the solar cell 20 was set to 24 mm. The width of the area of the solar cell module 1 in which the solar cells 20 could be disposed was set to 240 mm. The height D of the interrupting object 6 (i.e., height of the step) with respect to the installation surface S of the solar cell module 1 was set to 33.3 mm.

A filling factor of the solar cells 20 in this case was calculated by the formula (240−L)/240. Further, an increase in the power generation amount resulting from the reduced shaded area and the maximum point of power generation loss resulting from the reduced filling factor were obtained by multiplying the filling factor of the solar cells 20 by the annual power generation amount.

It was found from this simulation that the power generation amount was maintained at a high level regardless of whether the roof was installed north, north-northeast, east-northeast, or east, as long as L satisfied the following formula:

$${L}_{1} \leq L \leq {L}_{2}$$

where L1 represents the average shadow length at the summer solstice, and L2 represents the average shadow length at the winter solstice. Further, it was found from this simulation that the power generation amount was maintained at a high level regardless of whether the roof was installed north, north-northeast, east-northeast, or east, as long as L satisfied the following formula:

$${L}_{3} \leq L \leq {L}_{2} ,$$

where L3 represents an average shadow length at the autumn equinox, and L2 represents the average shadow length at the winter solstice.

Specifically, the following table shows PR values (Performance Ratio) calculated by the power generation amount/solar irradiance for the distances (L) from the step (interrupting object 6) of the solar cell module 1 to the solar cells and the installation azimuths of the roof (0° (installed to face north) to 90° (installed to face east)). The numerical values lining up vertically at an end of the table represent the distances while the numerical values lining up horizontally represent the azimuths. When the roof is installed at azimuths of 0 degree, 22.5 degrees, 45 degrees, 67.5 degrees, and 90 degrees in the north reference left-handed system, the average shadow lengths L1 at the summer solstice are 19, 19, 19, 18, and 17, respectively; the average shadow lengths L2 at the winter solstice are 212, 284, 307, 115, and 39, respectively; and the average shadow lengths L3 at the autumn equinox are 47, 47, 43, 34, and 24, respectively, corresponding to those azimuths at which the roof is installed.

TABLE 2

| | 0 degree | 22.5 degrees | 45 degrees | 67.5 degrees | 90 degrees |
|---|---|---|---|---|---|
| 0 | 34.6% | 37.5% | 44.0% | 50.2% | 55.3% |
| 5 | 39.2% | 41.0% | 47.2% | 53.2% | 57.7% |
| 10 | 43.8% | 44.7% | 50.2% | 55.4% | 59.5% |
| 15 | 48.2% | 48.3% | 52.6% | 57.2% | 60.7% |
| 20 | 51.9% | 51.3% | 54.5% | 58.4% | 61.4% |
| 30 | 54.9% | 55.2% | 56.8% | 59.3% | 61.4% |
| 40 | 55.2% | 56.0% | 57.3% | 58.8% | 60.3% |
| 50 | 54.6% | 55.2% | 56.4% | 57.4% | 58.5% |
| 75 | 50.1% | 50.5% | 51.4% | 51.7% | 52.1% |
| 100 | 43.6% | 44.3% | 44.6% | 44.6% | 44.8% |
| 150 | 29.0% | 29.1% | 29.1% | 29.1% | 29.1% |
| 200 | 13.1% | 13.0% | 13.0% | 13.0% | 13.0% |

When the solar cells 20 are disposed relatively away from the interrupting object 6 (L1<L), the PR value at each of the azimuths seems to have been improved by 10% or more as compared with the case of L<L1. In this simulation, the area in the solar cell module 1 in which the solar cells 20 can be disposed has a width set to 240 mm for calculations, thus, the most efficient result can be obtained when L=30 to 50 mm, which is considerably shorter than L2. When L=150 to 200 mm, the filling factor of the solar cells 20 decreases, resulting in a decreased PR value.

When the area in the solar cell module 20 in which the solar cells 20 can be placed has a width set to 480 mm, the PR values for the distances (L) from the step of the solar cell module 1 (interrupting object 6) to the solar cells and the installation azimuths of the roof (0 degree (installed to face north) to 90 degrees (installed to face east)) are shown in the table below.

TABLE 3

| | 0 degree | 22.5 degrees | 45 degrees | 67.5 degrees | 90 degrees |
|---|---|---|---|---|---|
| 0 | 34.6% | 37.5% | 44.0% | 50.2% | 55.3% |
| 5 | 39.6% | 41.5% | 47.7% | 53.7% | 58.3% |
| 10 | 44.8% | 45.7% | 51.3% | 56.6% | 60.8% |
| 15 | 49.8% | 49.9% | 54.4% | 59.1% | 62.8% |
| 20 | 54.2% | 53.7% | 57.0% | 61.0% | 64.2% |
| 30 | 58.8% | 59.1% | 60.9% | 63.5% | 65.8% |
| 40 | 60.7% | 61.6% | 63.0% | 64.7% | 66.3% |
| 50 | 61.8% | 62.4% | 63.9% | 65.0% | 66.2% |
| 75 | 61.5% | 62.0% | 63.1% | 63.4% | 64.0% |
| 100 | 59.2% | 60.1% | 60.5% | 60.5% | 60.8% |
| 150 | 53.2% | 53.4% | 53.4% | 53.3% | 53.3% |
| 200 | 45.7% | 45.7% | 45.6% | 45.5% | 45.5% |

As described above, the configuration that the area of the solar cell module 1 in which the solar cells 20 can be disposed has a large width can achieve a more efficient result by setting the L to a value close to the L2, as compared with the configuration that the width of the area is set to 240 mm.

It is a matter of course that the installation structure for the solar cell module of the present invention is not limited to the aforementioned embodiment, but various modifications can be made without departing from the gist of the present invention. For example, a configuration of an embodiment can be added to a configuration of another embodiment, and part of a configuration of an embodiment can be replaced by a configuration of another embodiment. Further, part of a configuration of an embodiment can be deleted.

The installation surface S of the solar cell module 1 of the aforementioned embodiment is the surface of the roof of a building, but can be an upper surface of a pedestal placed on, for example, the ground. The installation surface S can be a horizontal surface or an inclined surface (surface other than the vertical surface), and can be a surface of, for example, an exterior wall of a building.

In the solar cell string 2 of the aforementioned embodiment, the solar cells 20 each have an elongated shape and the plurality of solar cells 20 are connected to each other by the shingling connection, but the configuration can also be such that the solar cells 20 each have a shape other than the elongated shape, such as a square plate shape, and the plurality of solar cells 20 are connected to each other not by the shingling connection but by a wiring material.

As described above, according to the present invention, provided can be an installation structure for a solar cell module configured to suppress power output from being degraded by an interrupting object.

An installation structure for a solar cell module according to the present invention is an installation structure for a solar cell module including a solar cell string configured with a plurality of solar cells connected to each other, in which the solar cell module is disposed at a position shaded by an interrupting object that interrupts part of direct sunlight toward the solar cell module during a certain period of time of a day in a certain season, and a distance L between the interrupting object and a light-receiving surface end part of a solar cell closest to the interrupting object among the plurality of solar cells satisfies two formulas below:

$${L}_{k} = \frac{D}{b - a} {\int }_{a}^{b} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}} di$$

$${L}_{1} \leq L \leq {L}_{2}$$

where D represents a height of the interrupting object with respect to an installation surface of the solar cell module (height in a normal direction of the installation surface);
a represents a start time (hour-based) of a time range for which calculation is performed, and b represents an end time (hour-based) thereof;
in a zone to which an installation location of the solar cell module belongs, h_{k,i} represents a sun altitude (in degrees) at a time (hour-based) i of a date k, and φ_{k,i} represents a solar azimuth angle (in degrees) in a north reference left-handed system;
R_{φ} represents an azimuth angle (in degrees) in the north reference left-handed system at which the installation surface of the solar cell module faces, and R_{θ} represents an inclination angle (in degrees) of a light-receiving surface of the solar cell module relative to a horizontal plane; and
k=1 represents a date of the summer solstice, and k=2 represents a date of the winter solstice.

Such a configuration that the distance L between the interrupting object and the light-receiving surface end part of the solar cell closest to the interrupting object is set with the above two formulas can minimize the effect of the shadow cast by the interrupting object. The configuration that the effect of the shadow cast by the interrupting object is thus minimized can suppress power output from being degraded by the interrupting object.

In the installation structure for the solar cell module, the configuration can also be such that the distance L between the interrupting object and the light-receiving surface end part of the solar cell closest to the interrupting object among the plurality of solar cells further satisfies two formulas below:

$${L}_{k} = \frac{D}{6} {\sum }_{i = 9}^{14} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}}$$

$${L}_{1} \leq L \leq {L}_{2}$$

where, in the zone to which the installation location of the solar cell module belongs, h_{k,i} represents a sun altitude (in degrees) at a time i:30 on the date k, and φ_{k,i} represents a solar azimuth angle (in degrees) in the north reference left-handed system.

Such a configuration that the distance L between the interrupting object and the light-receiving surface end part of the solar cell closest to the interrupting object is set with the above two formulas can minimize the effect of the shadow cast by the interrupting object. The configuration that the effect of the shadow cast by the interrupting object is thus minimized can suppress power output from being degraded by the interrupting object.

In the installation structure for the solar cell module, the configuration can also be such that the solar cell string is formed of the plurality of solar cells connected to each other by shingling connection.

Such a configuration that the solar cell string is formed by the shingling connection enables the distance between the interrupting object or another solar cell module and the solar cells to be optimally adjusted depending on the number of solar cells connected in series and the width of overlapping between each adjacent ones of the solar cells.

In the installation structure for the solar cell module, the configuration can also be such that the solar cell module is installed at −90 to 90 degrees in the Northern Hemisphere, and at 90 to 270 degrees in the Southern Hemisphere, in the north reference left-handed system.

Such a configuration can minimize the effect of the shadow cast by the interrupting object when, for example, the solar cell module is installed to face north in the Northern Hemisphere and to face south in the Southern Hemisphere.

In the installation structure for the solar cell module, the configuration can also be such that the installation surface is a surface of a roof of a building.

Such a configuration can minimize the effect of the shadow cast by the interrupting object when the solar cell module is installed on the roof.

In the installation structure for the solar cell module, the configuration can also be such that the solar cell module includes a light-transmitting layer on a light incident side, and the light-transmitting layer is subjected to an antiglare treatment.

Such a configuration can suppress light pollution caused by reflected light in an area close to the position at which the solar cell module is installed.

### REFERENCE SIGNS LIST

1: Solar cell module
2: Solar cell string
3: Light-transmitting layer
4: Sealing material
5: Resin sheet
6: Interrupting object
20, 21: Solar cell
210: Light-receiving surface end part
k: Date
L: Distance
S: Installation surface

1. An installation structure for a solar cell module comprising a solar cell string configured with a plurality of solar cells connected to each other, wherein
the solar cell module is disposed at a position shaded by an interrupting object that interrupts part of direct sunlight toward the solar cell module during a certain period of time of a day in a certain season, and
a distance L between the interrupting object and a light-receiving surface end part of a solar cell closest to the interrupting object among the plurality of solar cells satisfies two formulas below:
$${L}_{k} = \frac{D}{b - a} {\int }_{a}^{b} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}} di$$
$${L}_{1} \leq L \leq {L}_{2}$$
where D represents a height of the interrupting object with respect to an installation surface of the solar cell module (height in a normal direction of the installation surface);
a represents a start time (hour-based) of a time range for which calculation is performed, and b represents an end time (hour-based) thereof,
in a zone to which an installation location of the solar cell module belongs, h_{k,i} represents a sun altitude (in degrees) at a time (hour-based) i of a date k, and φ_{k,i} represents a solar azimuth angle (in degrees) in a north reference left-handed system;
R_{φ} represents an azimuth angle (in degrees) in the north reference left-handed system at which the installation surface of the solar cell module faces, and R_{θ} represents an inclination angle (in degrees) of a light-receiving surface of the solar cell module relative to a horizontal plane; and
k=1 represents a date of the summer solstice, and k=2 represents a date of the winter solstice.

2. The installation structure for the solar cell module according to claim 1, wherein the distance L between the interrupting object and the light-receiving surface end part of the solar cell closest to the interrupting object among the plurality of solar cells further satisfies two formulas below:
$${L}_{k} = \frac{D}{6} {\sum }_{i = 9}^{14} \frac{\begin{matrix}- cos {h}_{k , i} sin {ϕ}_{k , i} cos {R}_{θ} sin {R}_{ϕ} - \\ cos {h}_{k , i} cos {ϕ}_{k , i} cos {R}_{θ} cos {R}_{ϕ} + sin {h}_{k , i} sin {R}_{θ}\end{matrix}}{\begin{matrix}cos {h}_{k , i} sin {ϕ}_{k , i} sin {R}_{θ} sin {R}_{ϕ} + \\ cos {h}_{k , i} cos {ϕ}_{k , i} sin {R}_{θ} cos {R}_{ϕ} + sin {h}_{k , i} cos {R}_{θ}\end{matrix}}$$
$${L}_{1} \leq L \leq {L}_{2}$$
where, in the zone to which the installation location of the solar cell module belongs, h_{k,i} represents a sun altitude (in degrees) at a time i:30 on the date k, and φ_{k,i} represents a solar azimuth angle (in degrees) in the north reference left-handed system.

3. The installation structure for the solar cell module according to claim 1, wherein the solar cell string is formed of the plurality of solar cells connected to each other by shingling connection.

4. The installation structure for the solar cell module according to claim 1, wherein the solar cell module is installed at −90 to 90 degrees in the Northern Hemisphere, and at 90 to 270 degrees in the Southern Hemisphere, in the north reference left-handed system.

5. The installation structure for the solar cell module according to claim 1, wherein the installation surface is a surface of a roof of a building.

6. The installation structure for the solar cell module according to claim 1, wherein the solar cell module comprises a light-transmitting layer on a light incident side, and
the light-transmitting layer is subjected to an antiglare treatment.

7. The installation structure for the solar cell module according to claim 2, wherein the solar cell string is formed of the plurality of solar cells connected to each other by shingling connection.

8. The installation structure for the solar cell module according to claim 2, wherein the solar cell module is installed at −90 to 90 degrees in the Northern Hemisphere, and at 90 to 270 degrees in the Southern Hemisphere, in the north reference left-handed system.

9. The installation structure for the solar cell module according to claim 2, wherein the installation surface is a surface of a roof of a building.

10. The installation structure for the solar cell module according to claim 2, wherein the solar cell module comprises a light-transmitting layer on a light incident side, and
the light-transmitting layer is subjected to an antiglare treatment.
